(19) United States
(12) Patent Application Publication
(10) Pub. No.: US 2019/0371904 A1
(43) Pub. Date: Dec. 5, 2019

(54) THIN FILM TRANSISTOR AND MANUFACTURING METHOD THEREOF, ARRAY SUBSTRATE AND DISPLAY DEVICE

(71) Applicants: Chongqing BOE Optoelectronics Technology Co., Ltd., Chongqing (CN); BOE Technology Group Co., Ltd., Beijing (CN)

(72) Inventors: Jun Wang, Beijing (CN); Zhonghao Huang, Beijing (CN); Yongliang Zhao, Beijing (CN); Seungmoo Rim, Beijing (CN)

(21) Appl. No.: 16/341,534

(22) PCT Filed: Sep. 26, 2018
(86) PCT No.: PCT/CN2018/107513

§ 371 Date: Apr. 12, 2019

(30) Foreign Application Priority Data
Sep. 26, 2017 (CN) 201721240582.6

(51) Int. Cl. H01L 29/49; H01L 27/12; H01L 29/66; H01L 21/28

(52) U.S. Cl. CPC H01L 29/4908; H01L 29/4966; H01L 29/4925; H01L 21/28088; H01L 29/66742; H01L 21/2807; H01L 27/1214

(57) ABSTRACT

A thin film transistor and manufacturing methods thereof, an array substrate and a display device are provided. The thin film transistor includes a base substrate, a gate layer, a gate insulating layer, an active layer, and a source/drain layer. The gate layer includes a first gate layer, and a second gate layer between the first gate layer and the gate insulating layer. The first gate layer is a metal layer. The second gate layer is a doped semiconductor material layer. The gate insulating layer is usually made from SiO, SiN or the like.

### CROSS-REFERENCE TO RELATED APPLICATION

This application is a 371 of PCT Patent Application Serial No. PCT/CN2018/107513, filed on Sep. 26, 2018, which claims priority to Chinese Utility Model Application No. 201721240582.6, filed on Sep. 26, 2017 and entitled “Thin Film Transistor, Array Substrate and Display Device”, the entire contents of which are incorporated herein by reference.

### TECHNICAL FIELD

The present disclosure relates to a thin film transistor and manufacturing methods thereof, an array substrate and a display device.

### BACKGROUND

A thin film transistor (TFT) is an important part of a liquid crystal display (LCD). Generally, TFTs can be classified into top-gate TFTs and a bottom-gate TFTs according to different hierarchical orders. As an example, the bottom-gate TFT basically includes a base substrate, as well as a gate layer, a gate insulating layer, an active layer and a source/drain (S/D) layer sequentially laminated on the base substrate.

### SUMMARY

Embodiments of the present disclosure provide a thin film transistor and manufacturing methods thereof, an array substrate and a display device. The technical solutions are as follows.

At least one embodiment of the present disclosure provides a thin film transistor, comprising a base substrate, a gate layer, a gate insulating layer, an active layer and a source/drain layer, wherein the gate layer comprises a first gate layer, and a second gate layer between the first gate layer and the gate insulating layer, the first gate layer is a metal layer, and the second gate layer is a doped semiconductor material layer

In an implementation of the embodiments of the present disclosure, an orthographic projection of the active layer on the base substrate and an orthographic projection of the second gate layer on the base substrate meet one of the following relationships: the orthographic projection of the active layer on the base substrate is within the orthographic projection of the second gate layer on the base substrate; and the orthographic projection of the active layer on the base substrate coincides with the orthographic projection of the second gate layer on the base substrate.

In an implementation of the embodiments of the present disclosure, the second gate layer is one of an N-type heavily-doped amorphous silicon layer, a P-type heavily-doped amorphous silicon layer, an indium gallium zinc oxide layer, an N-type low-temperature poly-silicon layer and a P-type low-temperature poly-silicon layer.

In an implementation of the embodiments of the present disclosure, the second gate layer has a thickness range of 300-500 Å.

In an implementation of the embodiments of the present disclosure, the first gate layer is one of a copper layer and an aluminum layer.

In an implementation of the embodiments of the present disclosure, the first gate layer has a thickness range of 3,000-5,000 Å.

In an implementation of the embodiments of the present disclosure, the gate insulating layer is one of a SiO layer, a SiN layer and a SiON layer.

In an implementation of the embodiments of the present disclosure, the gate layer, the gate insulating layer, the active layer and the source/drain layer are sequentially laminated on the base substrate.

In an implementation of the embodiments of the present disclosure, the source/drain layer, the active layer, the gate insulating layer and the gate layer are sequentially laminated on the base substrate.

At least one embodiment of the present disclosure provides an array substrate, comprising the mentioned thin film transistor.

At least one embodiment of the present disclosure provides a display device, comprising the mentioned array substrate.

At least one embodiment of the present disclosure provides a manufacturing method applied to the foregoing thin film transistor, comprising: manufacturing the metal layer on the base substrate; patterning the metal layer to obtain the first gate layer; manufacturing the doped semiconductor material layer on the first gate layer; patterning the doped semiconductor material layer to obtain the second gate layer; and forming the gate insulating layer on the second gate layer.

At least one embodiment of the present disclosure provides a manufacturing method applied to the foregoing thin film transistor, comprising: manufacturing the metal layer on the base substrate; manufacturing the doped semiconductor material layer on the metal layer; patterning the metal layer and the doped semiconductor material layer to obtain the first gate layer and the second gate layer; and forming the gate insulating layer on the second gate layer.

At least one embodiment of the present disclosure provides a manufacturing method applied to the foregoing thin film transistor, comprising: manufacturing the doped semiconductor material layer on the gate insulating layer; patterning the doped semiconductor material layer to obtain the second gate layer; manufacturing the metal layer on the second gate layer; and patterning the metal layer to obtain the first gate layer.

At least one embodiment of the present disclosure provides a manufacturing method applied to the foregoing thin film transistor, comprising: manufacturing the doped semiconductor material layer on the gate insulating layer; manufacturing the metal layer on the doped semiconductor material layer; and patterning the doped semiconductor material layer and the metal layer to obtain the first gate layer and the second gate layer.

### BRIEF DESCRIPTION OF THE DRAWINGS

FIG. 1 is a structural schematic diagram of a TFT according to an embodiment of the present disclosure;

FIG. 2 is a structural schematic diagram of another TFT according to an embodiment of the present disclosure;

FIG. 3 is a structural schematic diagram of a TFT during the manufacturing process according to an embodiment of the present disclosure;

FIG. 4 is a structural schematic diagram of a TFT during the manufacturing process according to an embodiment of the present disclosure;

FIG. 5 is a structural schematic diagram of a TFT during the manufacturing process according to an embodiment of the present disclosure;

FIG. 6 is a structural schematic diagram of a TFT during the manufacturing process according to an embodiment of the present disclosure;

FIG. 7 is a structural schematic diagram of a TFT during the manufacturing process according to an embodiment of the present disclosure;

FIG. 8 is a structural schematic diagram of a TFT during the manufacturing process according to an embodiment of the present disclosure;

FIG. 9 is a structural schematic diagram of a TFT during the manufacturing process according to an embodiment of the present disclosure;

FIG. 10 is a structural schematic diagram of a TFT during the manufacturing process according to an embodiment of the present disclosure;

FIG. 11 is a structural schematic diagram of a TFT during the manufacturing process according to an embodiment of the present disclosure; and

FIG. 12 is a structural schematic diagram of a TFT according to an embodiment of the present disclosure.

### DETAILED DESCRIPTION

The embodiments of the present disclosure will be described in further detail with reference to the accompanying drawings, to clearly present the objects, technical solutions, and advantages of the present disclosure.

In a TFT, the gate is usually made of metal, e.g., copper (Cu) and aluminum (Al). The gate insulating layer is generally made from SiO2, SiN or the like. In the TFT made of the above-mentioned materials, due to the material lattice mismatch between the gate and the gate insulating layer, a lattice mismatch is caused between the gate and the gate insulating layer. There exist lots of interface states, which affects the performance of the TFT. Moreover; the threshold voltage of the TFT is relevant to the work function of the gate material. When the gate is made of a certain metal material, the value of the threshold voltage of the TFT is set due to the set work function of the metal material. Consequently, when the gate is made of the certain metal material, the TFT manufactured is single in threshold voltage, which is difficult to satisfy the requirement for various threshold voltages.

Embodiments of the present disclosure provide a TFT, a manufacturing method thereof, an array substrate and a display device, which can solve the problems of lots of interface states between the gate and the gate insulating layer and single threshold voltage of the TFT in the related art.

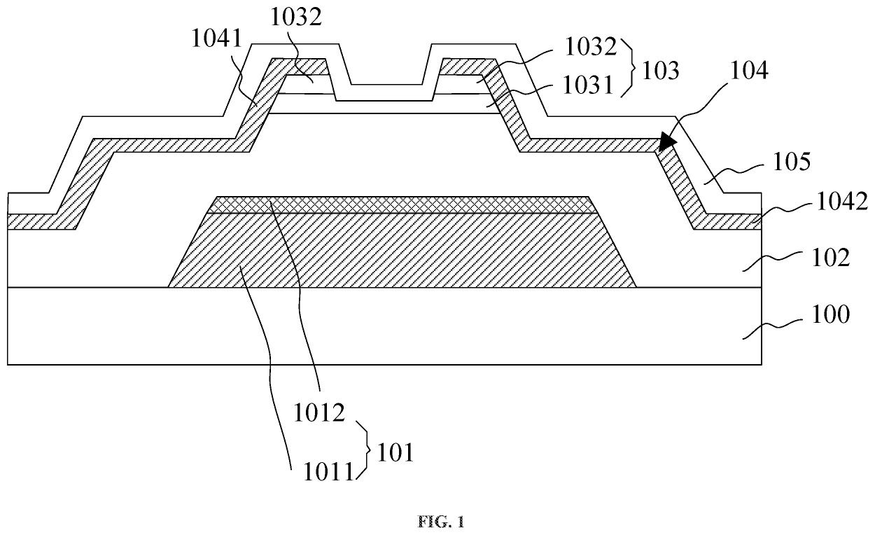

FIG. 1 is a structural schematic diagram of a TFT according to an embodiment of the present disclosure. Referring to FIG. 1, the TFT includes a base substrate TOO, a gate layer 101, a gate insulating layer 102, an active layer 103 and an S/I) layer 104. Here, the gate layer 101 includes a first gate layer 1011 made of metal material, and a second gate layer 1012 between the first gate layer 1011 and the gate insulating layer 102. The second gate layer 1012 is a doped semiconductor material layer. The first gate layer 1011 is made of a metal material, that is, the first gate layer 1011 is a metal layer.

In the embodiments of the present disclosure, the second gate layer 1012 is between the first gate layer 1011 and the gate insulating layer 102 means that a side surface of the second gate layer 1012 is in contact with the first gate layer 1011, and the other side surface of the second gate layer 1012 is in contact with the gate insulating layer 102.

In the TFT, the gate includes the following two portions: the first gate layer made of metal, and a second gate layer made of a doped semiconductor material. The second gate layer is located between the first gate layer and the gate insulating layer to change the interface between the gate and the gate insulating layer in the related design from a metal/SiO (or SiN) interface to a semiconductor/SiO (or SiN) interface. Compared with the metal/SiO (or SiN) interface, the semiconductor/SiO (or SiN) interface reduces the defect density between the gate and the gate insulating layer. Interface states are lowered. Thus, the sub-threshold swing and hysteresis of the TFT are effectively improved, which can make the speed of turning on/off the TFT faster. Meanwhile, the uniformity of the threshold voltage of the TFT can be guaranteed, thereby improving the performance of the TFT. Besides, the work function of the gate material of the TFT can be changed by adjusting the doping amount of semiconductors in the second gate layer, to further adjust the threshold voltage of the manufactured TFT.

Two functions of the second gate layer in the TFT will be described in detail with reference to formulas.

1. Improve the TFT's Performance:

The computational formula of the sub-threshold swing S of the TFT is as below:

$$S = \frac{KT}{q} \times ln 10 \times [ 1 + \frac{\sqrt{{q}^{2} {ɛ}_{0} {ɛ}_{s} {N}_{s}}}{{C}_{i}} + \frac{{q}^{2} {N}_{it}}{{C}_{i}} ] \qquad ( 1 )$$

In formula (I), K is Boltzmann constant, T represents temperature, q represents electron charge, ln 10 is a logarithm of 10 with an irrational number e as a base number, ε₀ is vacuum dielectric constant. εₛ is dielectric constant of the semiconductor (the active layer), Cᵢ is capacitance of the gate insulating layer, Nₛ is the number of fixed charges in the semiconductor (the active layer), and Nᵢₜ represents defect density of interface. The semiconductor is the active layer made of the semiconductor in the TFT.

Based on formula (1): first, the second gate layer and the gate insulating layer form a Si/SiO (or SiN) interface. In comparison with the traditional metal/SiO (or SiN) interface, interface defects can be reduced. The density of the interface defects is reduced. That is, Nit in the formula is reduced. Thus, the sub-threshold swing S calculated in accordance with the formula is reduced. The sub-threshold swing of the TFT can be effectively improved. Second, the number of the interface defects will also influence the bending of the energy band of the semiconductor, which will affect the flat band voltage. When the density of the interface defects is large, the flat band voltage is unstable, which will lead to an unstable threshold voltage. According to the embodiment of the present disclosure, the interface defects are greatly lowered, the density of the interface defects is reduced, and the degree of instability of the flat band voltage is reduced, which has a function of improving the uniformity of the threshold voltage. Third, hysteresis of the TFT is also in strong correlation with the interface defects. Once the interface defects are lowered, the hysteresis of the TFT will be improved.

2. Adjust TFT's Threshold Voltage

The computational formula of the flat band voltage is as below:

V_{fb}=(Wₛ−Wₘ)/q (2)

The flat band voltage V_{fb} refers to the gate voltage which needs to be applied for energy band leveling of the semiconductor. In formula (2), Wₘ is a work function of the gate, Wₛ is a work function of the active layer, and q is an electron charge. The work function Wm of the second gate layer may be adjusted by adjusting the doping amount of the second gate layer, so as to adjust the flat band voltage V_{fb}. However, the threshold voltage Vₜₕ is exactly determined by the flat band voltage V_{fb} and a channel inversion layer formation voltage Vₜ. Vₜₕ=V_{fb}+Yₜ. Thus, the work function Wm of the second gate layer may be changed by adjusting the doping amount of the second gate layer, thereby changing the flat band voltage V_{fb}, to realize the adjustment of the threshold voltage Vₜₕ.

In the embodiments of the present disclosure, the second gate layer 1012 may be an N-type heavily-doped amorphous silicon (N+a-Si) layer, a P-type heavily-doped amorphous silicon (P+a-Si) layer, an indium gallium zinc oxide (IGZO) layer, an IN-type low-temperature poly-silicon (LIPS) layer or a P-type low-temperature poly-silicon (LIPS) layer. When the second gate layer 1012 is made from these materials, on the one hand, the density of interface states between the metal gate and the gate insulating layer may be reduced. On the other hand, the threshold voltage of the TFT may be adjusted by adjusting the doping amount of the semiconductor material layer.

Exemplarily, the IGZO layer may adjust the doping amount of O to adjust the threshold voltage of the TFT. In the a-Si or LIPS, N-type doping may be phosphorus doping, and P-type doping may be boron doping. The threshold voltage of the TFT is adjusted by adjusting the doping amount of phosphorus or boron. Certainly, the above-mentioned materials of the second gate layer are merely exemplary. The second gate layer may also be made from other doped semiconductor materials, which will not be limited by the embodiments of the present disclosure.

In the embodiments of the present disclosure, the second gate layer 1012 may have a thickness range of 300-500 Å. The second gate layer is made to be 300-500 Å in thickness to guarantee its film forming on the one hand, and to improve the performance and adjust the threshold voltage of the TFT on the other hand.

Exemplarily, the second gate layer 1012 may have a thickness of 400 Å or 450 Å.

In the embodiments of the present disclosure, the orthographic projection of the active layer 103 on the base substrate 100 is located within or coincides with the orthographic projection of the second gate layer 1012 on the base substrate 100. That is, the dimension of the second gate layer 1012 needs to guarantee that the second gate layer 1012 can fully cover an overlapping region between the first gate layer 1011 and the active layer 103, namely, to guarantee that the second gate layer 1012 is disposed at a portion (a channel region) between the first gate layer 1011 and the active layer 103.

Since the threshold voltage of the TFT is relevant to the projection region of the active layer on the gate (it is also relevant to the gate insulating layer, but the gate insulating layer is not discussed in the present disclosure and it is assumed that the impact of the gate insulating layer is a fixed value), when the second gate layer 1012 fully covers the overlapping region between the first gate layer 1011 and the active layer 103, the projection region of the active layer on the gate is totally located on the second gate layer. Here, the threshold voltage of the TFT is only relevant to the second gate layer but is not related to the first gate layer. Thus, it is guaranteed that the threshold voltage is only affected by the second gate layer, to realize the stability of the threshold voltage and to regulate and control the second gate layer by adjusting the doping density of the second gate layer.

Exemplarily, the orthographic projection of the active layer 103 on the base substrate 100 is located within the orthographic projection of the second gate layer 1012 on the base substrate 100. In this design, the second gate layer 1012 has a relatively big area and does not completely correspond to the active layer 103. Thus, the demands on precision and a manufacture process are low.

In the embodiment of the present disclosure, the first gate layer 1011 may be a Cu layer or an Al layer. When Cu or Al is used as the metal material of the gate, the resistance is small and electric conductivity is strong, which can guarantee the electric conductivity of the gate.

In the embodiments of the present disclosure, the first gate layer 1011 may have a thickness range of 3,000-5,000 Å, which avoids the entire TFT from being too thick due to the thickness of the first gate layer 1011, and avoids the gate from being poor in electric conductivity due to an extremely small thickness of the first gate layer 1011.

In the embodiments of the present disclosure, the gate insulating layer 102 may be Sit) layer, a SiN layer or a SiON layer. The gate insulating layer 102 made from these materials has an excellent insulating property. When the gate with the double-layered structure is used, the interface states between the gate and the gate insulating layer 102 may be reduced, and thus the overall performance of the TFT may be improved.

The TFT provided in the embodiments of the present disclosure may be a bottom-gate TFT or a top-gate TFT. In the embodiments of the present disclosure, the structure of the bottom-gate TFT is as shown in FIG. 1. The gate layer 101, the gate insulating layer 102, the active layer 103 and the S/D layer 104 are sequentially laminated on the base substrate 100.

In the embodiments of the present disclosure, the base substrate 100 may be a transparent substrate, such as a glass substrate, a silicon substrate, or a plastic substrate, etc.

In the embodiment of the present disclosure, the active layer 103 may be made from amorphous silicon, microcrystalline silicon, or poly-silicon. For example, the active layer 103 may include an amorphous silicon layer 1031 disposed on the gate insulating layer 102 and an N-type doped amorphous silicon layer 1032 disposed on the amorphous silicon layer 1031. By disposing the N-type doped amorphous silicon layer on the amorphous silicon layer, direct contact between the amorphous silicon layer and the S/D layer can be avoided, and the lattice mismatch between the amorphous silicon layer and the S/D layer is reduced.

In the embodiment of the present disclosure, the S/D layer 104 and the first gate layer 1011 may be made of the same material, for example, Cu or Al. The S/D layer 104 includes a source 1041 and a drain 1042 facing each other.

Further, the TFT may further include a passivation layer 105 disposed on the S/D layer 104. The passivation layer 105 is disposed to protect the TFT. Here, the passivation layer may be a SiN layer or SiON layer. A via hole (not shown) is formed in the passivation layer 105, such that the S/D layer 104 is communicated with a pixel electrode layer disposed on the passivation layer 105.

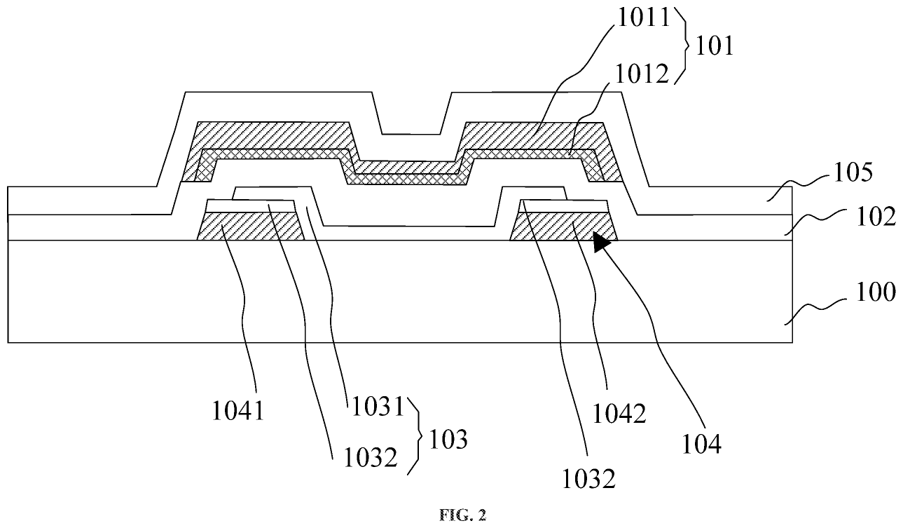

FIG. 2 is a structural schematic diagram of another TFT according to an embodiment of the present disclosure. Referring to FIG. 2, the TFT is a top-gate TFT, in which an S/D layer 104, an active layer 103, a gate insulating layer 102 and a gate layer 101 are sequentially laminated on a base substrate 100.

In the top-gate TFT, a second gate layer 1012 is disposed on the gate insulating layer 102. A first gate layer 1011 is disposed on the second gate layer 1012.

In the top-gate TFT, an N-type doped amorphous silicon layer 1032 is disposed on the S/D layer 104. An amorphous silicon layer 1031 is disposed on the N-type doped amorphous silicon layer 1032.

In the top-gate TFT, a passivation layer 105 is disposed on the gate layer 101.

The manufacturing process of the gate layer 101 in FIG. 1 and FIG. 2 will be described below with reference to the accompanying drawings.

The gate in FIG. 1 may be manufactured in the following two ways.

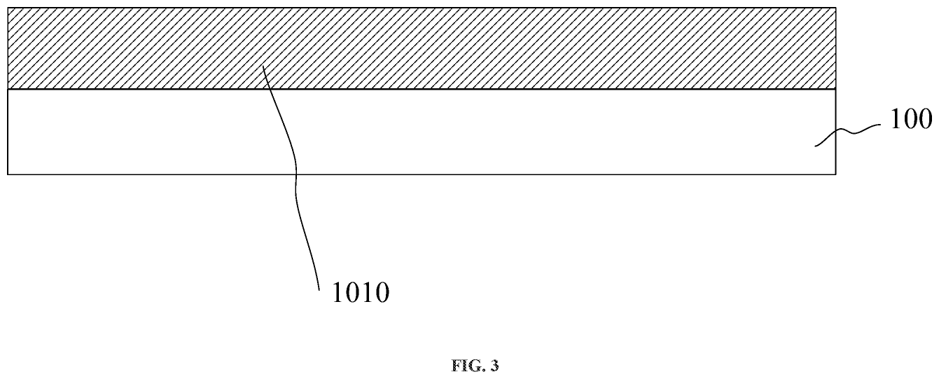

The first way: FIGS. 3-5 are structural schematic diagrams of a TFT during a manufacturing process according to an embodiment of the present disclosure. Referring to FIGS. 3-5, the manufacturing process includes the following steps.

In Step 1, a metal layer is manufactured on a base substrate. As shown in FIG. 3, a base substrate 100 is provided first. Then, a metal layer 1010 is manufactured on the base substrate 100. The metal layer 1010 may be manufactured by means of evaporation, sputtering or the like.

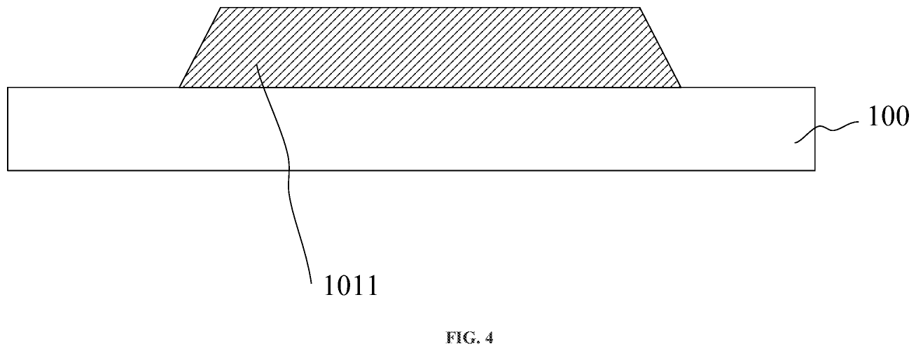

In Step 2, the metal layer is patterned to obtain a first gate layer. The metal layer 1010 on the base substrate 100 in FIG. 3 is patterned to form the first gate layer 1011 as shown in FIG. 4, The metal layer 1010 may be patterned by means of dry etching or wet etching.

Said patterning the metal layer 1010 may include: coating the metal layer 1010 with a photoresist; performing exposure and developing on the photoresist to form a photoresist pattern; and etching the metal layer 1010 through the photoresist pattern by means of wet etching or dry etching.

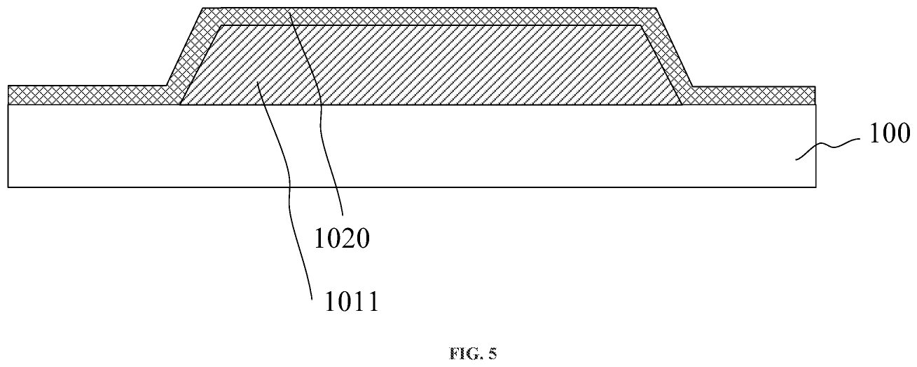

In Step 3, a doped semiconductor material layer is manufactured on the first gate layer. As shown in FIG. 5, the semiconductor material layer 1020 is manufactured on the base substrate 100 on which the first gate layer 1011 is manufactured. The semiconductor material layer 1020 may be manufactured by means of deposition or the like.

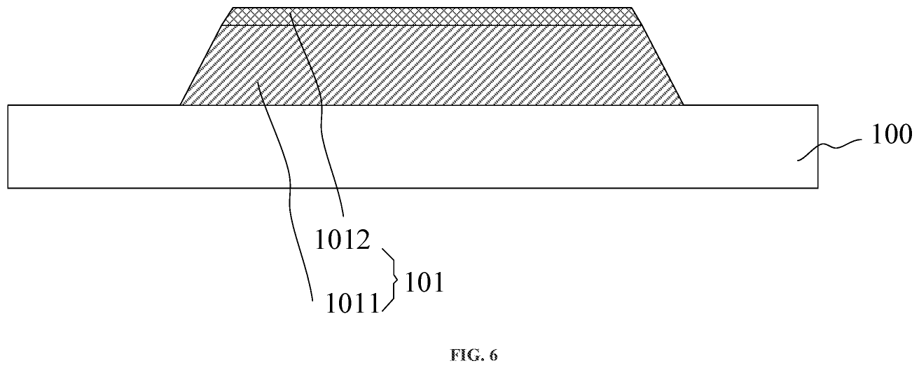

In Step 4, the doped semiconductor material layer is patterned to obtain a second gate layer. The semiconductor material layer 1020 on the base substrate 100 in FIG. 5 is patterned to form the second gate layer 1012 as shown in FIG. 6. The semiconductor material layer 1020 may be patterned by means of dry etching or wet etching.

After step 4, a gate insulating layer may be formed on the second gate layer. Then, other film layers, for example, an active layer and an S/D layer, of the TFT are formed.

By manufacturing the gate in this way, the problems that lots of interface states exist between the gate and the gate insulating layer of the bottom-gate TFT and it is difficult to adjust the threshold voltage of the TFT can be solved. In this manufacturing method, the two gate layers are formed by twice patterning processes, respectively.

The second way: FIGS. 3, 7 and 6 are structural schematic diagram of a TFT during a manufacturing process according to an embodiment of the present disclosure. Referring to FIGS. 3, 7 and 6, the manufacturing process may include the following steps.

In Step 1, a metal layer is manufactured on a base substrate. As shown in FIG. 3, a base substrate 100 is provided first. Then, a metal layer 1010 is manufactured on the base substrate 100. The metal layer 1010 may be manufactured by means of evaporation, sputtering or the like.

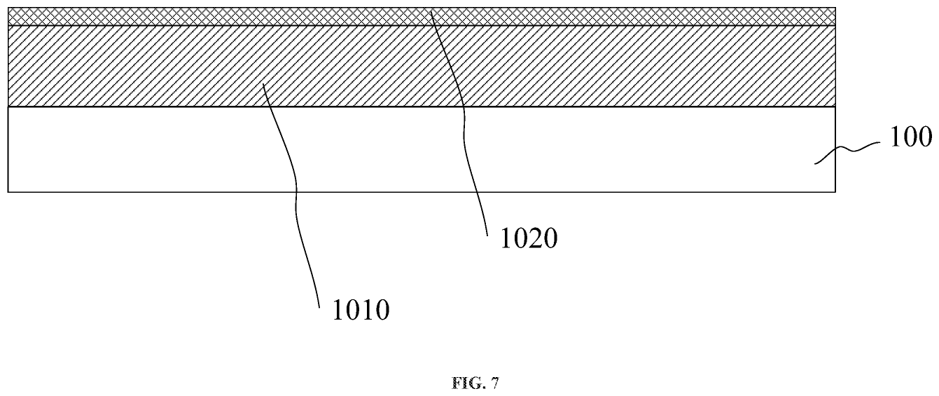

In Step 2, a doped semiconductor material layer is manufactured on the metal layer. As shown in FIG. 7, a semiconductor material layer 1020 is manufactured on the metal layer 1010. The semiconductor material layer 1020 may be manufactured by means of deposition or the like.

In Step 3, the metal layer and the doped semiconductor material layer are patterned to obtain a first gate layer and a second gate layer. The metal layer 1010 and the semiconductor material layer 1020 on the base substrate 100 in FIG. 7 are patterned to form a first gate layer 1011 and a second gate layer 1012 as shown in FIG. 6. The metal layer 1010 and the semiconductor material layer 1020 may be patterned by means of dry etching in one step or dry wet etching in two steps. The wet etching process in two steps may include: etching the semiconductor material layer 1020 with an etching liquid first to form the second gate layer 1012, and then etching the metal layer 1010 with another etching liquid to form the first gate layer 1011.

After step 3, a gate insulating layer may be formed on the second gate layer. Then, other film layers, for example, an active layer and an S/D layer, of the TFT are formed.

By manufacturing the gate in this way, the problems that lots of interface states exist between the gate and the gate insulating layer of the bottom-gate TFT and it is difficult to adjust the threshold voltage of the TFT are solved. In this manufacturing method, the two gate layers are formed through one-time patterning.

The gate in FIG. 2 may be manufactured in the following two ways.

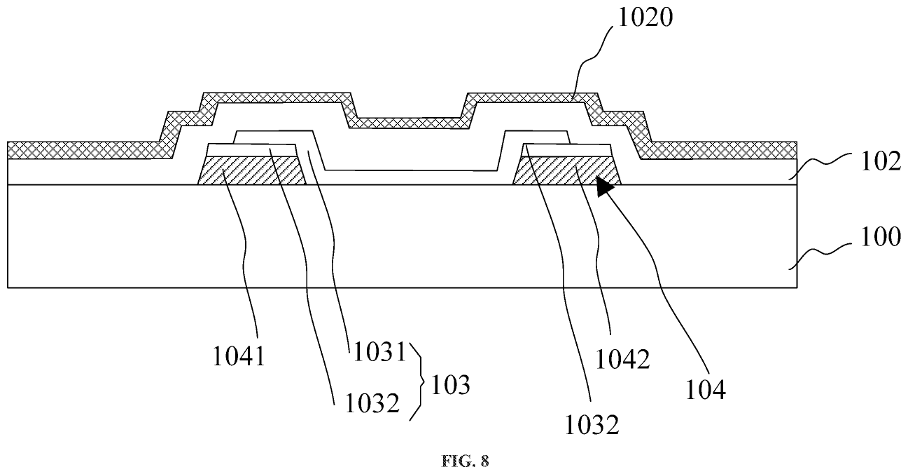

The first way: FIGS. 8-11 are structural schematic diagrams of a TFT during a manufacturing process according to an embodiment of the present disclosure. Referring to FIGS. 8-11, the manufacturing process may include the following steps:

In Step 1, a doped semiconductor material layer is manufactured on the gate insulating layer of the TFT. As shown in FIG. 8, after manufacture of the gate insulating layer 102 of the TFT, a semiconductor material layer 1020 is manufactured on the gate insulating layer 102. The semiconductor material layer 1020 may be manufactured by means of deposition or the like.

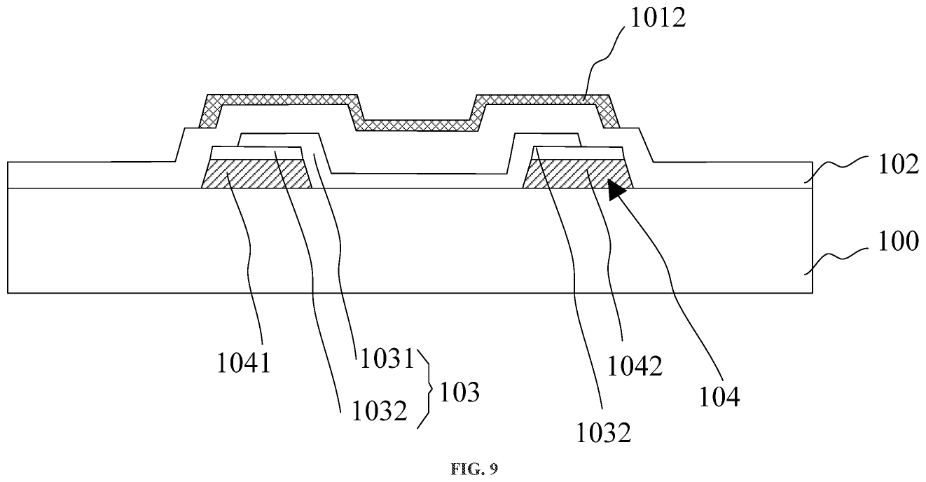

In Step 2, the doped semiconductor material layer is patterned to obtain a second gate layer. The semiconductor material layer 1020 on the gate insulating layer 102 in FIG. 8 is patterned to form the second gate layer 1012 as shown in FIG. 9. The semiconductor material layer 1020 may be patterned by means by dry etching or wet etching.

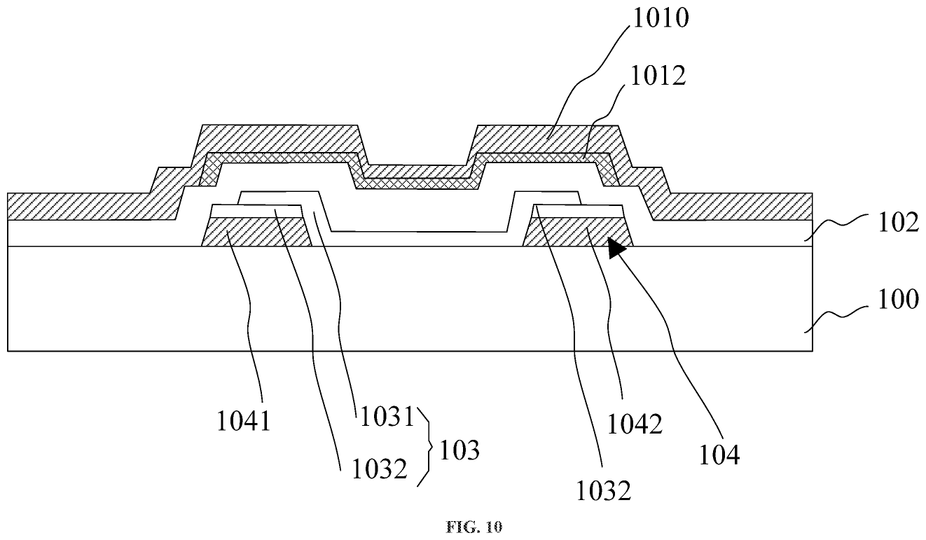

In Step 3, a metal layer is manufactured on the second gate layer. As shown in FIG. 10, a metal layer 1010 is manufactured on the gate insulating layer 102 on which the second gate layer 1012 is manufactured. The metal layer 1010 may be manufactured by means of evaporation, sputtering or the like.

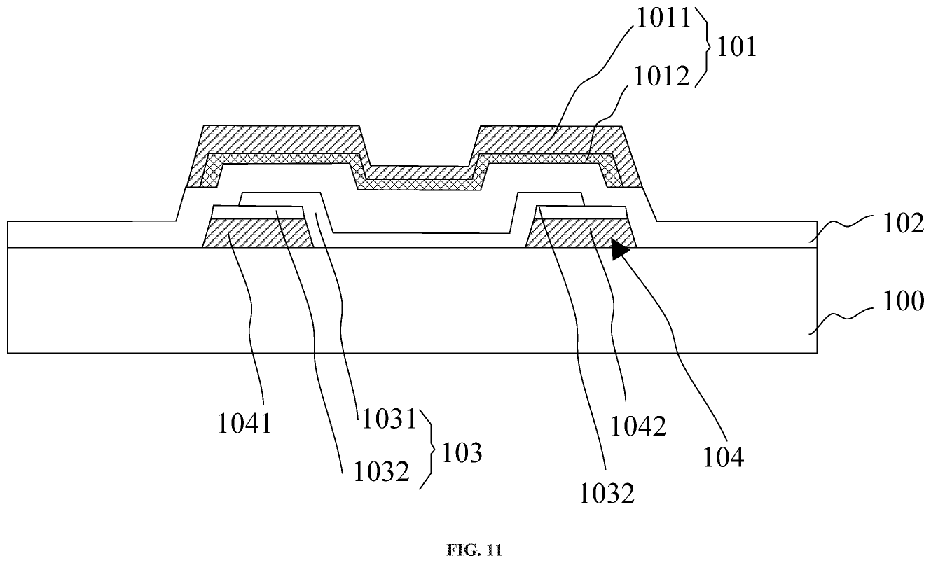

In Step 4, the metal layer is patterned to obtain a first gate layer. The metal layer 1010 on the gate insulating layer 102 in FIG. 10 is patterned to form the first gate layer 1011 as shown in FIG. 11. The metal layer 1010 may be patterned by means of dry etching or wet etching.

Before step 1, an S/D layer, an active layer and the gate insulating layer may be formed on the base substrate in advance.

By manufacturing the gate in this way, the problems that lots of interface states exist between the gate and the gate insulating layer of the top-gate TFT and it is difficult to adjust the threshold voltage of the TFT are solved. In this manufacturing method, the two gate layers are formed by twice patterning processes, respectively.

The second way: EEGs. 8, 12 and 11 are structural schematic diagrams of a TFT during a manufacturing process according to an embodiment of the present disclosure. Referring to FIGS. 8, 12 and 11, the manufacturing process may include the following steps.

In Step 1, a doped semiconductor material layer is manufactured on the gate insulating layer of the TFT. As shown in FIG. 8, after manufacture of the gate insulating layer 102 of the TFT, the semiconductor material layer 1020 is manufactured on the gate insulating layer 102. The semiconductor material layer 1020 may be manufactured by means of deposition or the like.

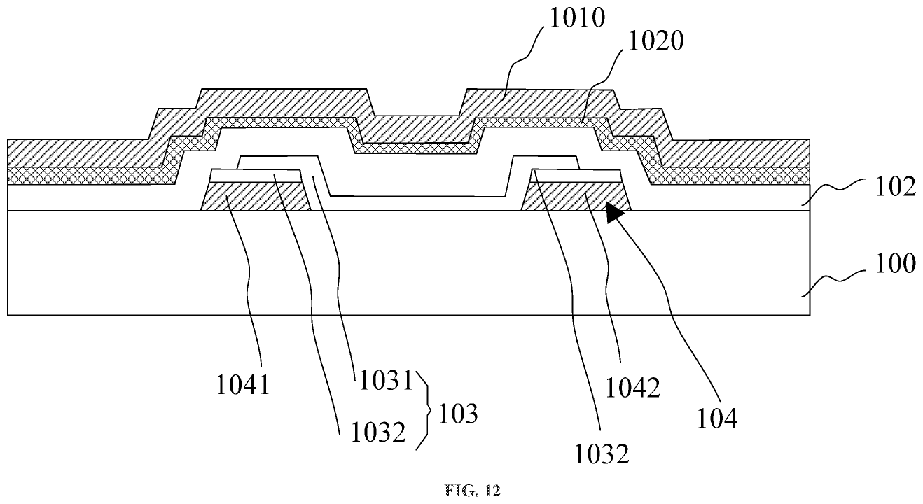

In Step 2, a metal layer is manufactured on the doped semiconductor material layer. As shown in FIG. 12, the metal layer 1010 is manufactured on the semiconductor material layer 1020. The metal layer 1010 may be manufactured by means of evaporation, sputtering or the like.

In Step 3, the doped semiconductor material layer and the metal layer are patterned to obtain a first gate layer and a second gate layer. The semiconductor material layer 1020 and the metal layer 1010 on the gate insulating layer 102 in FIG. 12 are patterned to form the second gate layer 1012 and the first gate layer 1011 as shown in FIG. 11. The semiconductor material layer 1020 and the metal layer 1010 may be patterned by means of dry etching in one step or by wet etching in two steps. The wet etching process in two steps may include: etching the metal layer 1010 with an etching liquid to form the first gate layer 1011, and then, etching the semiconductor material layer 1020 with another etching liquid to form the second gate layer 1012.

Before step 1, an S/D layer, an active layer and the gate insulating layer may be formed on the base substrate in advance.

By manufacturing the gate is in this way, the problems that lots of interface states exist between the gate and the gate insulating layer of the top-gate TFT and it is difficult to adjust the threshold voltage of the TFT are solved. In this manufacturing method, the two gate layers are formed by a one-time patterning process.

An embodiment of the present disclosure further provides an array substrate, which includes the TFT as shown in FIG. 1 or FIG. 2.

In the TFT of the array substrate provided in the embodiment of the present disclosure, the gate of the TFT includes the following two portions: the first gate layer made of metal, and a second gate layer made from a doped semiconductor material. The second gate layer is located between the first gate layer and the gate insulating layer to change an interface between the gate and the gate insulating layer in the related design from a metal/SiO (or SiN) interface to a semiconductor/SiO (or SiN) interface. Compared with the metal/SiO (or SiN) interface, in semiconductor/SiO (or SiN) interface, the defect density between the gate and the gate insulating layer is reduced, and interface states are reduced. Thus, sub-threshold swing and hysteresis of the TFT are effectively improved, which can make. the switching speed of the TFT faster. Meanwhile, the uniformity of the threshold voltage of the TFT can be guaranteed, thereby improving the performance of the TFT. Besides, the work function of the gate material of the TFT may be changed by adjusting the doping amount of semiconductors in the second gate layer. Thus, the threshold voltage of the manufactured TFT can be adjusted.

An embodiment of the present disclosure further provides a display device, including the foregoing array substrate.

In the embodiment of the present disclosure, the display device may be any product or component with a display function, such as a mobile phone, a tablet PC, a television, a display, a laptop, a digital photo frame or a navigator.

In the TFT of the display device provided in the embodiment of the present disclosure, the gate of the TFT includes the following two portions: the first gate layer made of metal, and a second gate layer made from a doped semiconductor material. The second gate layer is located between the first gate layer and the gate insulating layer to change an interface between the gate and the gate insulating layer in the related design from a metal/SiO (or SiN) interface to a semiconductor/SiO (or SiN) interface. Compared with the metal/SiO (or SiN) interface, in semiconductor/SiO (or SiN) interface, the defect density between the gate and the gate insulating layer is reduced, and interface states are reduced. Thus, sub-threshold swing and hysteresis of the TFT are effectively improved, which can make the switching speed of the TFT faster. Meanwhile, the uniformity of the threshold voltage of the TFT can be guaranteed, thereby improving the performance of the MT. Besides, the work function of the gate material of the TFT may be changed by adjusting the doping amount of semiconductors in the second gate layer. Thus, the threshold voltage of the manufactured TFT can be adjusted.

The foregoing descriptions are merely exemplary embodiments of the present disclosure, and are not intended to limit the present disclosure. Within the spirit and principles of the disclosure, any modifications, equivalent substitutions, improvements, etc., are within the protection scope of the appended claims of the present disclosure.

What is claimed is:

1. A thin film transistor, comprising a base substrate, a gate layer, a gate insulating layer, an active layer and a source/drain layer, wherein the gate layer comprises a first gate layer, and a second gate layer between the first gate layer and the gate insulating layer, the first gate layer is a metal layer, and the second gate layer is a doped semiconductor material layer.

2. The thin film transistor according to claim 1, wherein an orthographic projection of the active layer on the base substrate is within an orthographic projection of the second gate layer on the base substrate.

3. The thin film transistor according to claim 1, wherein an orthographic projection of the active layer on the base substrate coincides with an orthographic projection of the second gate layer on the base substrate.

4. The thin film transistor according to claim 1, wherein the second gate layer is one of an N-type heavily-doped amorphous silicon layer, a P-type heavily-doped amorphous silicon layer, an indium gallium zinc oxide layer, an N-type low-temperature poly-silicon layer and a P-type low-temperature poly-silicon layer.

5. The thin film transistor according to claim 1, wherein the second gate layer has a thickness range of 300-500 Å.

6. The thin film transistor according to claim 1, wherein the first gate layer is one of a copper layer and an aluminum layer.

7. The thin film transistor according to claim 1, wherein the first gate layer has a thickness range of 3,000-5,000 Å.

8. The thin film transistor according to claim 1, wherein the gate insulating layer is one of a SiO layer, a SiN layer and a SiON layer.

9. The thin film transistor according to claim 1, wherein the gate layer, the gate insulating layer, the active layer and the source/drain layer are sequentially laminated on the base substrate.

10. The thin film transistor according to claim 1, wherein the source/drain layer, the active layer, the gate insulating layer and the gate layer are sequentially laminated on the base substrate.

11. An array substrate, comprising a thin film transistor, wherein
the thin film transistor comprises a base substrate, a gate layer, a gate insulating layer, an active layer and a source/drain layer, the gate layer comprises a first gate layer, and a second gate layer between the first gate layer and the gate insulating layer, the first gate layer is a metal layer, and the second gate layer is a doped semiconductor material layer.

12. The array substrate according to claim 11, wherein an orthographic projection of the active layer on the base substrate is within an orthographic projection of the second gate layer on the base substrate.

13. The array substrate according to claim 11, wherein an orthographic projection of the active layer on the base substrate coincides with an orthographic projection of the second gate layer on the base substrate.

14. The array substrate according to claim 11, wherein the second gate layer is one of an N-type heavily-doped amorphous silicon layer, a P-type heavily-doped amorphous silicon layer, an indium gallium zinc oxide layer, an N-type low-temperature poly-silicon layer and a P-type low-temperature poly-silicon layer.

15. The array substrate according to claim 11, wherein the second gate layer has a thickness range of 300-500 Å.

16-19. (canceled)

20. A display device, comprising an array substrate which comprises a thin film transistor;
wherein the thin film transistor comprises a base substrate, a gate layer, a gate insulating layer, an active layer and a source/drain layer, wherein the gate layer comprises a first gate layer, and a second gate layer between the first gate layer and the gate insulating layer, the first gate layer is a metal layer, and the second gate layer is a doped semiconductor material layer.

21. A manufacturing method applied to the thin film transistor of claim 1, comprising:
manufacturing the metal layer on the base substrate;
patterning the metal layer to obtain the first gate layer;
manufacturing the doped semiconductor material layer on the first gate layer;
patterning the doped semiconductor material layer to obtain the second gate layer; and
forming the gate insulating layer on the second gate layer.

22. A manufacturing method applied to the thin film transistor of claim 1, comprising:
manufacturing the metal layer on the base substrate;
manufacturing the doped semiconductor material layer on the metal layer;
patterning the metal layer and the doped semiconductor material layer to obtain the first gate layer and the second gate layer; and
forming the gate insulating layer on the second gate layer.

23. A manufacturing method applied to the thin film transistor of claim 1, comprising:
manufacturing the doped semiconductor material layer on the gate insulating layer;
patterning the doped semiconductor material layer to obtain the second gate layer;
manufacturing the metal layer on the second gate layer; and
patterning the metal layer to obtain the first gate layer.

24. A manufacturing method applied to the thin film transistor of claim 1, comprising:
manufacturing the doped semiconductor material layer on the gate insulating layer;
manufacturing the metal layer on the doped semiconductor material layer; and
patterning the doped semiconductor material layer and the metal layer to obtain the first gate layer and the second gate layer.
